(19) United States
(12) Patent Application Publication
(10) Pub. No.: US 2025/0185168 A1
(43) Pub. Date: Jun. 5, 2025

(54) CIRCUIT MODULE

(71) Applicant: Murata Manufacturing Co., Ltd., Nagaokakyo-shi (JP)

(72) Inventor: Yoshihito OTSUBO, Nagaokakyo-shi (JP)

(21) Appl. No.: 19/049,793

(22) Filed: Feb. 10, 2025

Related U.S. Application Data
(63) Continuation of application No. PCT/JP2023/023735, filed on Jun. 27, 2023.

(30) Foreign Application Priority Data
Aug. 10, 2022 (JP) 2022-127727

(51) Int. Cl. H05K 1/14; H05K 1/18; H05K 3/28

(52) U.S. Cl. CPC H05K 1/144; H05K 1/181; H05K 3/284; H05K 2201/042; H05K 2201/0715; H05K 2201/1003; H05K 2201/10242

(57) ABSTRACT

In a circuit module, a lower circuit board, when viewed in an up-down direction, overlaps with a portion of an upper circuit board. The upper circuit board, the lower circuit board, and a sealing member configure a main body portion including an upper surface, a lower surface, and a side surface connecting the upper surface and the lower surface. A shield member covers the upper surface and the side surface. When viewed in the up-down direction, the first component is located outside an outer end of the lower circuit board. A lower end of the first component is located below a second upper principal surface. When viewed in the up-down direction, a component mounted on the first lower principal surface or a connection member mounted on the first lower principal surface is absent between the side surface located closest to the first component and the first component.

### CROSS REFERENCE TO RELATED APPLICATION

This is a continuation of International Application No. PCT/JP2023/023735 filed on Jun. 27, 2023 which claims priority from Japanese Patent Application No. 2022-127727 filed on Aug. 10, 2022. The contents of these applications are incorporated herein by reference in their entireties.

### BACKGROUND OF THE DISCLOSURE

### Field of the Disclosure

The present disclosure relates to a circuit module including an upper circuit board and a lower circuit board.

### Description of the Related Art

As a disclosure related to the conventional circuit module, for example, a semiconductor device disclosed in U.S. Pat. No. 10,388,637 is known. This semiconductor device includes two circuit boards. The two circuit boards, when viewed in an up-down direction, overlap with each other. In addition, the two circuit boards are electrically connected to each other. Furthermore, the two circuit boards are integrated with each other by being sealed with a resin.

### BRIEF SUMMARY OF THE DISCLOSURE

Incidentally, in the field of the semiconductor device disclosed in Patent Literature 1, a circuit module having a new structure has been expected.

In view of the foregoing, exemplary embodiments of the present disclosure are directed to provide a circuit module having a new structure.

A circuit module according to an exemplary embodiment of the present disclosure includes an upper circuit board including a first upper principal surface and a first lower principal surface that are arranged in an up-down direction, a lower circuit board including a second upper principal surface and a second lower principal surface that are arranged in the up-down direction and disposed below the upper circuit board, a first component mounted on the first lower principal surface, a sealing member covering the first lower principal surface and the second upper principal surface, and a shield member, and the lower circuit board, when viewed in the up-down direction, overlaps with a portion of the upper circuit board, the upper circuit board, the lower circuit board, and the sealing member configure a main body portion including an upper surface, a lower surface, and a side surface connecting the upper surface and the lower surface, the shield member covers the side surface, when viewed in the up-down direction, the first component is located outside an outer end of the lower circuit board, a lower end of the first component is located below the second upper principal surface, and, when viewed in the up-down direction, a component mounted on the first lower principal surface and a connection member mounted on the first lower principal surface are absent between the side surface located closest to the first component and the first component.

According to the present disclosure, a circuit module having a new structure is provided.

### BRIEF DESCRIPTION OF THE SEVERAL VIEWS OF THE DRAWINGS

FIG. 1 is a cross-sectional view of a circuit module 10.

FIG. 2 is a view of a first lower principal surface S2 viewed in an up direction.

FIG. 3 is a block diagram of the circuit module 10.

FIG. 4 is a cross-sectional view of a circuit module 10a.

FIG. 5 is a view of a first lower principal surface S2 of a circuit module 10b viewed in the up direction.

FIG. 6 is a cross-sectional view of a circuit module 10c.

FIG. 7 is a view of a first lower principal surface S2 of the circuit module 10c viewed in the up direction.

FIG. 8 is a cross-sectional view of a circuit module 10d.

FIG. 9 is a view of a first lower principal surface S2 of the circuit module 10d viewed in the up direction.

FIG. 10 is a view of a first lower principal surface S2 of a circuit module 10e viewed in the up direction.

FIG. 11 is a view of a first lower principal surface S2 of a circuit module 10f viewed in the up direction.

FIG. 12 is a cross-sectional view of a circuit module 10g.

FIG. 13 is a view of a first lower principal surface S2 of the circuit module 10g viewed in the up direction.

### DETAILED DESCRIPTION OF THE DISCLOSURE

### Exemplary Embodiment

### (Structure of Circuit Module 10)

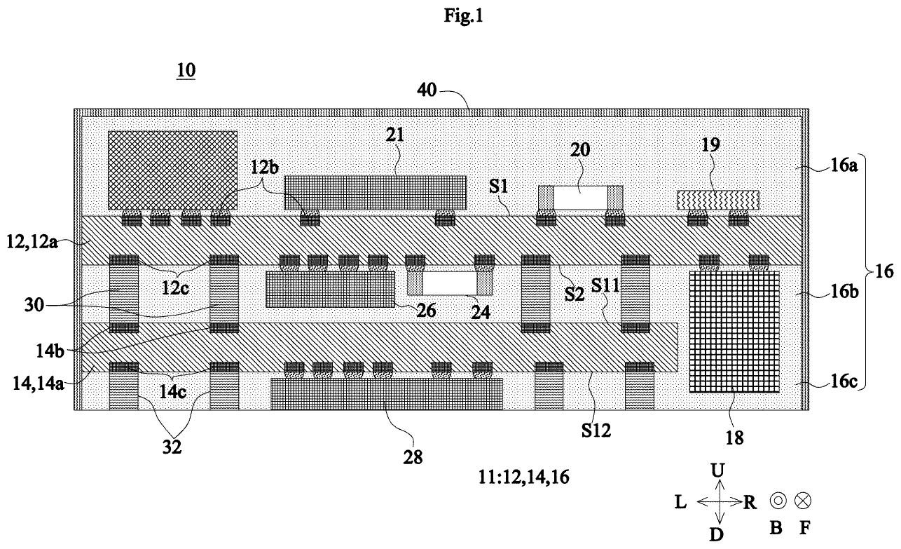

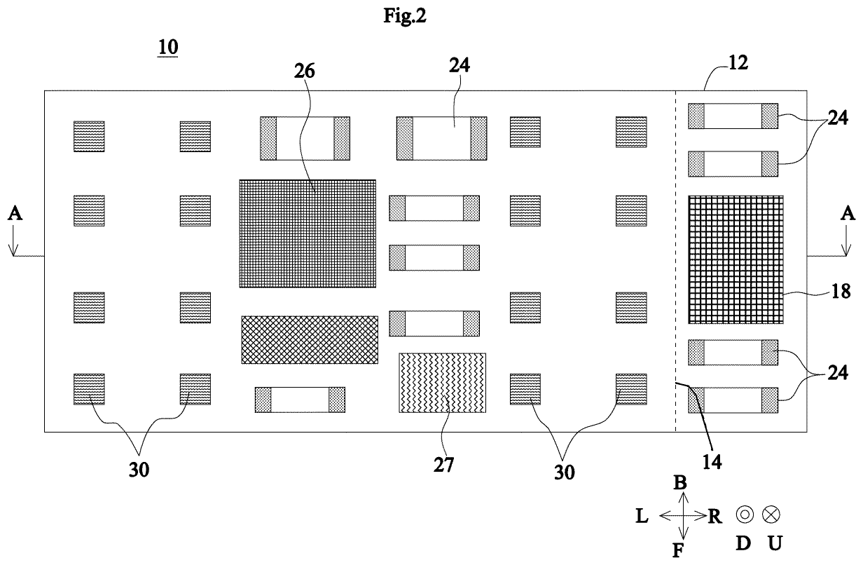

Hereinafter, a structure of a circuit module 10 according to an exemplary embodiment of the present disclosure will be described. FIG. 1 is a cross-sectional view of the circuit module 10. FIG. 1 shows a section taken along a line A-A in FIG. 2. FIG. 2 is a view of a first lower principal surface S2 viewed in an up direction. A dotted line in FIG. 2 shows a right short side of a lower circuit board 14.

Hereinafter, as shown in FIG. 1, a direction in which a first upper principal surface S1 and a first lower principal surface S2 of an upper circuit board 12 of the circuit module 10 are arranged is defined as an up-down direction. In addition, directions orthogonal to the up-down direction are defined as a front-back direction and a left-right direction. The front-back direction and the left-right direction are orthogonal to each other. The front-back direction matches a vertical direction of the sheet of FIG. 1. The left-right direction matches a left-right direction of the sheet of FIG. 1. However, the up-down direction, the left-right direction, and the front-back direction in the present specification are directions defined for convenience of description, and may not match the up-down direction, the left-right direction, and the front-back direction during the use of the circuit module 10. In addition, in each drawing, the up direction and the down direction may be switched, the left direction and the right direction may be switched, and the front direction and the back direction may be switched.

The circuit module 10 is used for a wireless communication terminal such as a smartphone. The circuit module 10 includes, for example, a semiconductor integrated circuit (a power amplifier of a transmission system, a low noise amplifier of a reception system), a coil or a capacitor as a matching circuit, or the like. The circuit module 10 has a rectangular parallelepiped shape. The circuit module 10, as shown in FIG. 1, includes an upper circuit board 12, a lower circuit board 14, a sealing member 16, electronic components 18, 19, 21, 26, and 28, a plurality of electronic components 20 and 24, a plurality of connection members 30 and 32, and a shield member 40. It is to be noted that, in the drawings, reference signs are only assigned to the representative electronic components 20 and 24 of the plurality of electronic components 20 and 24.

The upper circuit board 12 has the first upper principal surface S1 and the first lower principal surface S2 that are arranged in the up-down direction. More specifically, the upper circuit board 12 includes a board body 12a, a plurality of mounting electrodes 12b, and a plurality of mounting electrodes 12c. The board body 12a has a shape of a plate having the first upper principal surface S1 and the first lower principal surface S2. The board body 12a (the upper circuit board 12), when viewed in the up-down direction, has a rectangular shape having a front long side, a back long side, a left short side, and a right short side. The board body 12a has a multilayer structure. The board body 12a internally includes a not-illustrated electric circuit. The board body 12a is a glass-epoxy substrate or an LTCC-based substrate, for example.

The plurality of mounting electrodes 12b are provided on the first upper principal surface S1. The plurality of mounting electrodes 12c are provided on the first lower principal surface S2. The plurality of mounting electrodes 12b and the plurality of mounting electrodes 12c, when viewed in the up-down direction, have a rectangular shape or a circle shape. The plurality of mounting electrodes 12b and the plurality of mounting electrodes 12c, for example, have a structure in which Ni plating and Au plating is applied to a surface of a copper electrode.

The lower circuit board 14 has a second upper principal surface S11 and a second lower principal surface S12 that are arranged in the up-down direction. More specifically, the lower circuit board 14 includes a board body 14a, a plurality of mounting electrodes 14b, and a plurality of mounting electrodes 14c. The board body 14a has a shape of a plate having the second upper principal surface S11 and the second lower principal surface S12. The board body 14a (the lower circuit board 14), when viewed in the up-down direction, has a rectangular shape having a front long side, a back long side, a left short side, and a right short side. The board body 14a has a multilayer structure. The board body 14a internally includes a not-illustrated electric circuit. The material of the board body 14a is, for example, glass epoxy.

The plurality of mounting electrodes 14b are provided on the second upper principal surface S11. The plurality of mounting electrodes 14c are provided on the second lower principal surface S12. The plurality of mounting electrodes 14b and the plurality of mounting electrodes 14c, when viewed in the up-down direction, have a rectangular shape or a circle shape. The plurality of mounting electrodes 14b and the plurality of mounting electrodes 14c, for example, have a structure in which Ni plating and Au plating is applied to a surface of a copper thin film.

The lower circuit board 14 as described above is located below the upper circuit board 12. In addition, the lower circuit board 14, when viewed in the up-down direction, overlaps with a portion of the upper circuit board 12. An outer end of the lower circuit board 14, when viewed in the up-down direction, overlaps with at least a portion of at least two sides among the front long side, the back long side, the left short side, and the right short side of the upper circuit board 12. In the present exemplary embodiment, the left short side of the lower circuit board 14 overlaps with the left short side of the upper circuit board 12. The front long side of the lower circuit board 14 overlaps with a portion of the front long side of the upper circuit board 12. The back long side of the lower circuit board 14 overlaps with a portion of the back long side of the upper circuit board 12. The right short side of the lower circuit board 14 does not overlap with the right short side of the upper circuit board 12. As a result, the entirety of the lower circuit board 14, when viewed in the up-down direction, overlaps with a portion of the upper circuit board 12.

The plurality of connection members 32 have a rod shape extending in the up-down direction. The plurality of connection members 32 are metal pins. The plurality of connection members 32 are mounted on the second lower principal surface S12. More accurately, the plurality of connection members 32 are mounted on the plurality of mounting electrodes 14c. The plurality of connection members 32, when the circuit module 10 is mounted on a mother board, contacts a mounting electrode of the mother board. The material of the plurality of connection members 32 is a metal such as copper. In addition, Ni plating and Au plating may be applied to a surface of the plurality of connection members 32.

The plurality of connection members 30 have a rod shape extending in the up-down direction. The plurality of connection members (first connection members) 30 are metal pins. The plurality of connection members (the first connection members) 30 are mounted on the first lower principal surface S2 and the second upper principal surface S11. More accurately, the plurality of connection members 30 are mounted to the plurality of mounting electrodes 12c and the plurality of mounting electrodes 14b. As a result, the plurality of connection members 30 electrically connect the upper circuit board 12 and the lower circuit board 14. The material of the plurality of connection members 30 is a metal such as copper. In addition, Ni plating and Au plating may be applied to a surface of the plurality of connection members 30.

The electronic component (a first component) 18 is mounted on the first lower principal surface S2. In other words, the electronic component 18 is mounted to the plurality of mounting electrodes 12c. A lower end of the electronic component (the first component) 18 is located below the second upper principal surface S11. In the present exemplary embodiment, the lower end of the electronic component 18 is located below the second lower principal surface S12. In addition, when viewed in the up-down direction, the electronic component (the first component) 18 is located outside the outer end of the lower circuit board 14. When viewed in the up-down direction, the electronic component 18 is located on the right of the lower circuit board 14. As a result, the electronic component 18, when viewed in the up-down direction, does not overlap with the lower circuit board 14. The electronic component (the first component) 18 as described above is, for example, an inductor.

A plurality of electronic components 24 are mounted on the first lower principal surface S2. In other words, the electronic components 24 are mounted to the plurality of mounting electrodes 12c. The plurality of electronic components 24 are capacitors or inductors.

The electronic component 26 is mounted on the first lower principal surface S2. In other words, the electronic component 26 is mounted to the plurality of mounting electrodes 12c. The electronic component 26 is a filter.

The electronic component 27 is mounted on the first lower principal surface S2. In other words, the electronic component 27 is mounted to the plurality of mounting electrodes 12c. The electronic component 27 is a low noise amplifier.

The electronic component 19 is mounted on the first upper principal surface S1. In other words, the electronic component 19 is mounted to the plurality of mounting electrodes 12b. The electronic component 19 is a power amplifier. The electronic component (the power amplifier) 19, when viewed in the up-down direction, overlaps with the electronic component (the first component) 18.

The plurality of electronic components 20 are mounted on the first upper principal surface S1. In other words, the electronic components 20 is mounted to the plurality of mounting electrodes 12b. The plurality of electronic components 20 are capacitors or inductors.

The electronic component 21 is mounted on the first upper principal surface S1. In other words, the electronic component 21 is mounted to the plurality of mounting electrodes 12b. The electronic component 21 is a filter.

The electronic component 28 is mounted on the second lower principal surface S12. In other words, the electronic component 28 is mounted to the plurality of mounting electrodes 14c. The electronic component 28 is a switch IC.

The sealing member 16 includes sealing portions 16a to 16c. The sealing portion 16a covers the first upper principal surface S1. The sealing portion 16b covers the first lower principal surface S2 and the second upper principal surface S11. The sealing portion 16c covers the second lower principal surface S12. In addition, the sealing member 16 includes the electronic components 18, 19, 21, 26, and 28, the plurality of electronic components 20 and 24, and the plurality of connection members 30 and 32. The material of such a sealing member 16 is an insulating material. The insulating material is, for example, a resin.

The upper circuit board 12, the lower circuit board 14, and the sealing member 16 as described above define a main body portion 11. The main body portion 11 has a rectangular parallelepiped shape. Accordingly, the main body portion 11 has an upper surface, a lower surface, and a side surface connecting the upper surface and the lower surface. The side surface includes a front surface, a back surface, a left surface, and a right surface.

The shield member 40 covers the upper surface and the side surface of the main body portion 11. The shield member 40 is provided by performing sputtering, metal plating, or conductive paste application on the upper surface and the side surface of the main body portion 11. The shield member 40 is connected to a ground potential.

Herein, placement of the electronic component 18 will be described. As shown in FIG. 1 and FIG. 2, when viewed in the up-down direction, a component mounted on the first lower principal surface S2 or a connection member mounted on the first lower principal surface S2 is absent between the side surface of the main body portion 11 located closest to the electronic component (the first component) 18 and the electronic component (the first component) 18. The side surface of the main body portion 11 located closest to the electronic component 18 is the right surface of the main body portion 11. Therefore, only the sealing member 16 is present between the right surface of the main body portion 11 and the electronic component 18.

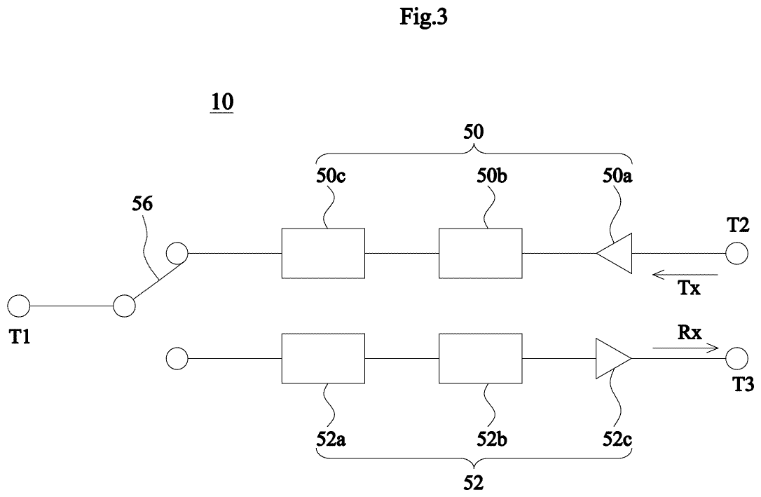

The circuit module 10 as described above is a front end module having a transmission circuit and a reception circuit. Hereinafter, a circuit configuration of the circuit module 10 will be described with reference to the accompanying drawings. FIG. 3 is a block diagram of the circuit module 10.

The circuit module 10 includes a transmission circuit 50, a reception circuit 52, and a switch IC 56. The transmission circuit 50 includes a power amplifier 50a, a matching circuit 50b, and a filter 50c. The power amplifier 50a, the matching circuit 50b, and the filter 50c are connected in series in this order. The power amplifier 50a is connected to a terminal T2. The filter 50c is connected to the switch IC 56. The reception circuit 52 includes a filter 52a, a matching circuit 52b, and a low noise amplifier 52c. The filter 52a, the matching circuit 52b, and the low noise amplifier 52c are connected in series to this order. The low noise amplifier 52c is connected to a terminal T3. The filter 52a is connected to the switch IC 56. In addition, the switch IC 56 is connected to a not-illustrated antenna through a terminal T1.

In the circuit module 10 as described above, when a transmission signal Tx is sent, the switch IC 56 electrically connects the terminal T1 and the transmission circuit 50. On the other hand, when a reception signal Rx is received, the switch IC 56 electrically connects the terminal T1 and the reception circuit 52.

Herein, the power amplifier 50a is the electronic component 19. Accordingly, the electronic component 19 is included in the transmission circuit 50. The matching circuit 50b is defined by the electronic component 18 and the plurality of electronic components 20. The filter 50c is the electronic component 21.

The filter 52a is the electronic component 26. The matching circuit 52b is defined by the plurality of electronic components 24. The low noise amplifier 52c is the electronic component 27. The switch IC 56 is the electronic component 28.

### Effects

In the circuit module 10, when viewed in the up-down direction, a component mounted on the first lower principal surface S2 or a connection member mounted on the first lower principal surface S2 is absent between the side surface of the main body portion 11 located closest to the electronic component (the first component) 18 and the electronic component 18. As a result, the circuit module 10 having a new structure is obtained.

According to the circuit module 10, noise generated by the electronic component 18 is significantly reduced from being emitted to the outside of the circuit module 10, and noise is also significantly reduced from intruding into the electronic component 18. More specifically, when viewed in the up-down direction, a component mounted on the first lower principal surface S2 or a connection member mounted on the first lower principal surface S2 is absent between the side surface of the main body portion 11 located closest to the electronic component 18 and the electronic component 18. Then, the shield member 40 covers the side surface of the main body portion 11. Accordingly, the shield member 40 is present near the electronic component 18. As a result, the noise generated by the electronic component 18 is absorbed by the shield member 40. In addition, the noise to intrude from the outside of the circuit module 10 into the circuit module 10 is absorbed by the shield member 40. As described above, the noise generated by the electronic component 18 is significantly reduced from being emitted to the outside of the circuit module 10, and the noise is also significantly reduced from intruding into the electronic component 18.

Moreover, in the circuit module 10, the lower end of the electronic component 18 is located below the second upper principal surface S11. Then, the electronic component 18 is an inductor. Such a large-sized inductor radiates noise having high strength. Accordingly, the circuit module 10 includes the structure, so that the noise generated by the electronic component 18 is more effectively significantly reduced from being emitted to the outside of the circuit module 10.

Furthermore, in the circuit module 10, the electronic component 18 is included in the transmission circuit 50. A signal of high strength is transmitted in the transmission circuit 50. Therefore, the electronic component 18 tends to emit the noise having high strength. Accordingly, the circuit module 10 including such a structure more effectively significantly reduces the noise generated by the electronic component 18 from being emitted to the outside of the circuit module 10.

In the circuit module 10, when viewed in the up-down direction, the electronic component 18 is located outside the outer end of the lower circuit board 14. Then, the lower end of the electronic component 18 is located below the second upper principal surface S11. Accordingly, the distance between the upper circuit board 12 and the lower circuit board 14 is below the height of the electronic component 18 in the up-down direction. As a result, the height of the circuit module 10 in the up-down direction is reduced.

In the circuit module 10, the electronic component 19 being the power amplifier 50a, when viewed in the up-down direction, overlaps with the electronic component 18 being the matching circuit 50b. As a result, the distance from the power amplifier 50a to the matching circuit 50b is reduced. Therefore, noise is significantly reduced from intruding into a signal path between the power amplifier 50a and the matching circuit 50b.

In the circuit module 10, the lower end of the electronic component 18 is located below the second upper principal surface S11. Accordingly, the electronic component 18 is brought close to a mother board on which the circuit module 10 is mounted. As a result, the electronic component 18 is shielded by a ground conductor of the mother board.

### First Modification

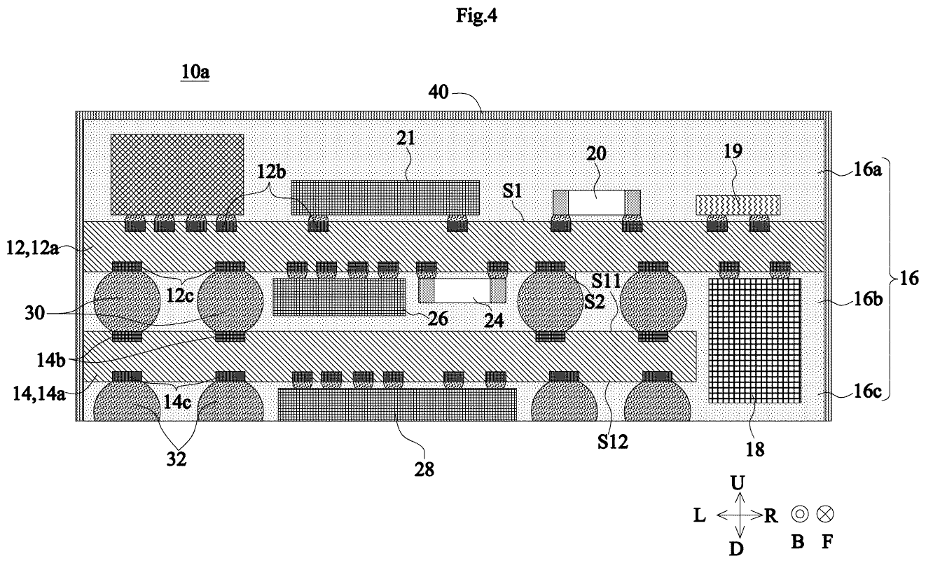

Hereinafter, a circuit module 10a according to a first modification of the present disclosure will be described with reference to drawings. FIG. 4 is a cross-sectional view of the circuit module 10a.

The circuit module 10a is different in the structure of the connection members 30 and 32 from the circuit module 10. The plurality of connection members 30 have a spherical shape. The plurality of connection members 32 have a hemispherical shape. The plurality of connection members 30 and 32 are solder bumps. Other structures of the circuit module 10a are the same as or similar to the structures of the circuit module 10, and a description of the same or similar configuration will be omitted. The circuit module 10a is able to produce the same operational effects as the circuit module 10.

### Second Modification

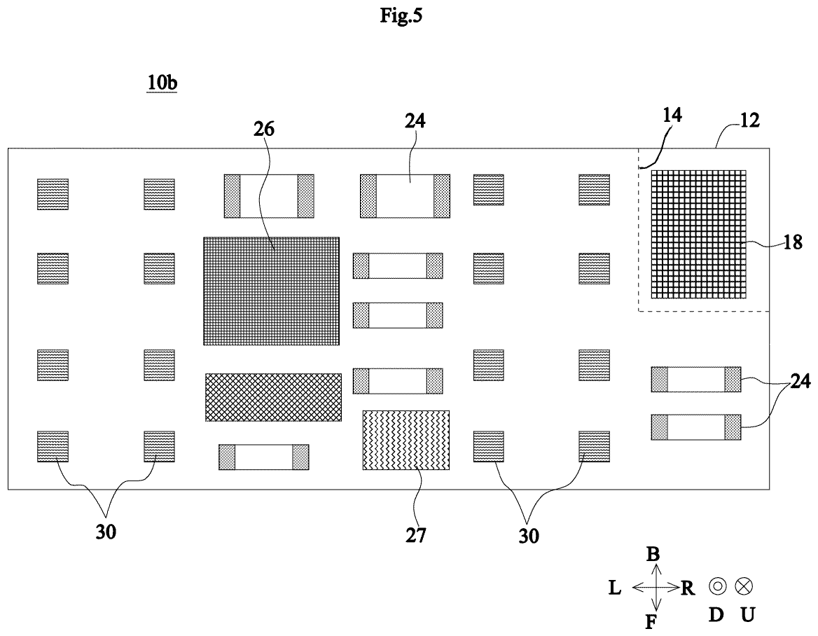

Hereinafter, a circuit module 10b according to a second modification of the present disclosure will be described with reference to drawings. FIG. 5 is a view of a first lower principal surface S2 of the circuit module 10b viewed in the up direction.

The circuit module 10b is different in the shape of the lower circuit board 14 from the circuit module 10. More specifically, the lower circuit board 14, when viewed in the up-down direction, does not overlap with a vicinity of the right back corner of the upper circuit board 12. Then, the electronic component 18 is mounted to the vicinity of the right back corner of the first lower principal surface S2. Other structures of the circuit module 10b are the same as or similar to the structures of the circuit module 10, and a description of the same or similar configuration will be omitted. The circuit module 10b is able to produce the same operational effects as the circuit module 10.

### Third Modification

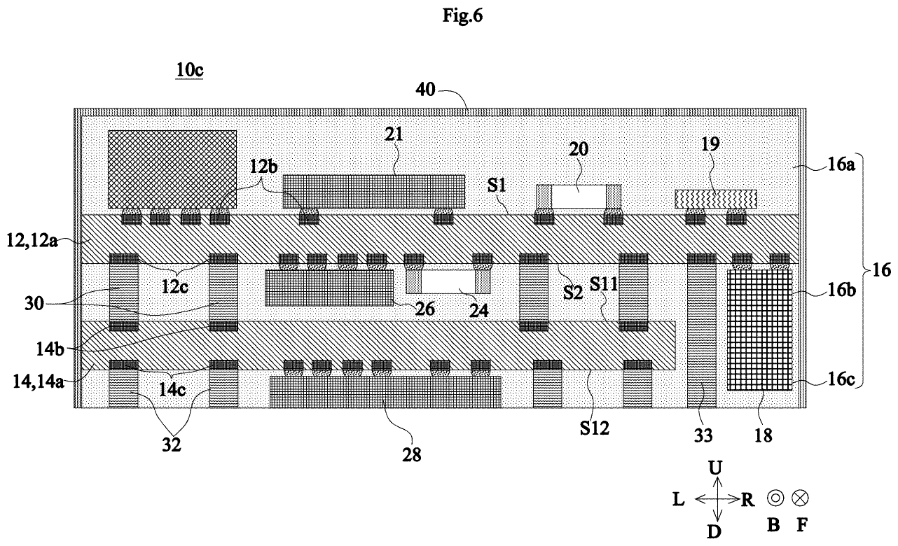

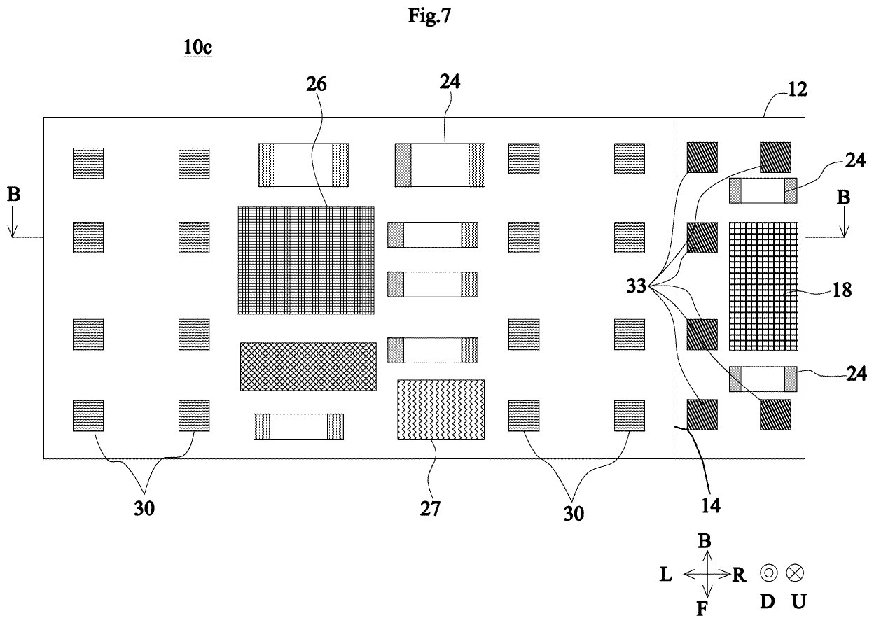

Hereinafter, a circuit module 10c according to a third modification of the present disclosure will be described with reference to drawings. FIG. 6 is a cross-sectional view of the circuit module 10c. FIG. 6 shows, for example, a cross-section taken along a line B-B in FIG. 7. FIG. 7 is a view of a first lower principal surface S2 of the circuit module 10c viewed in the up direction.

The circuit module 10c is different from the circuit module 10 in that a plurality of connection members 33 are further provided. The plurality of connection members (second connection members) 33, when viewed in the up-down direction, are located outside the outer end of the lower circuit board 14. In the present exemplary embodiment, the plurality of connection members 33 are located on the right of the lower circuit board 14. The plurality of connection members 33, when viewed in the up-down direction, are placed around the electronic component 18. Then, a component mounted on the first lower principal surface S2 or a connection member mounted on the first lower principal surface S2 is absent between two connection members 33 (a part of the plurality of connection members 33) among the plurality of connection members 33 and the electronic component (the first component) 18. The two connection members 33 are located on the left of the electronic component 18. The plurality of connection members 33 are mounted on the first lower principal surface S2. In addition, the plurality of connection members 33 are exposed outside the main body portion 11 on a lower surface of the main body portion 11. The plurality of connection members (the second connection members) 33 as described above are connected to a ground potential. Other structures of the circuit module 10c are the same as or similar to the structures of the circuit module 10, and a description of the same or similar configuration will be omitted. The circuit module 10c is able to produce the same operational effects as the circuit module 10. The connection member 33 may not be metal pins or plating but may have a structure having vertically connected bumps.

In addition, in the circuit module 10c, a component mounted on the first lower principal surface S2 or a connection member mounted on the first lower principal surface S2 is absent between the two connection members 33 among the plurality of connection members 33 and the electronic component 18. Then, the plurality of connection members 33 are connected to a ground potential.

As a result, the noise generated by the electronic component 18 is absorbed by the plurality of connection member 33. In addition, the noise generated by the electronic component located on the left of the electronic component 18 is absorbed by the plurality of connection members 33.

### Fourth Modification

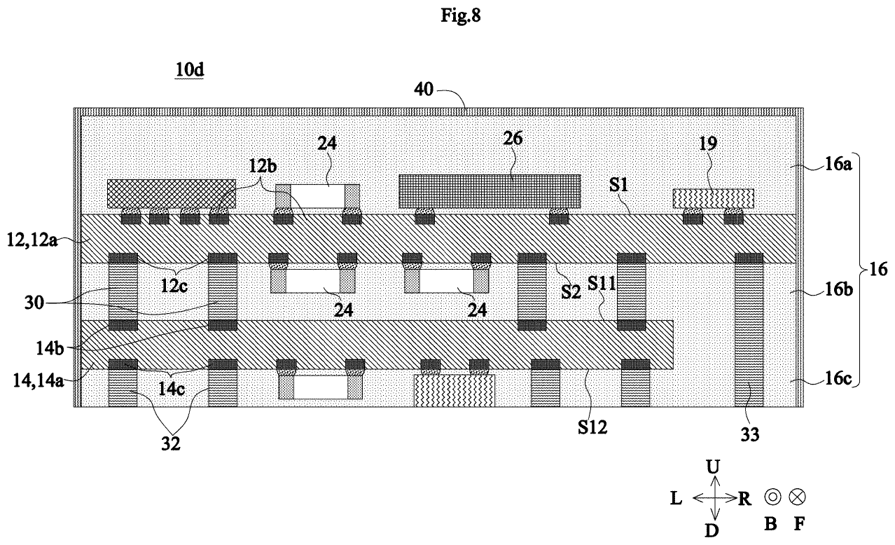

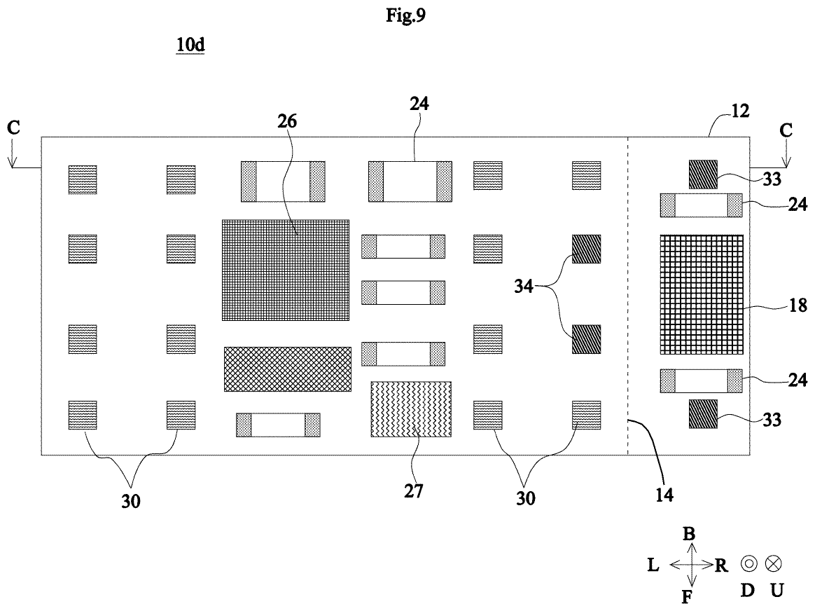

Hereinafter, a circuit module 10d according to a fourth modification of the present disclosure will be described with reference to drawings. FIG. 8 is a cross-sectional view of the circuit module 10d. FIG. 8 shows, for example, a cross-section taken along a line C-C in FIG. 9. FIG. 9 is a view of a first lower principal surface S2 of the circuit module 10d viewed in the up direction.

The circuit module 10d is different from the circuit module 10c in that two connection members 34 are further provided. More specifically, the connection members 33 are not present on the left of the electronic component 18. Then, the two connection members 34 are located on the left of the electronic component 18. The two connection members 34 are mounted on the first lower principal surface S2 and the second upper principal surface S11. The plurality of connection members 34 as described above are connected to a ground potential. Other structures of the circuit module 10d are the same as or similar to the structures of the circuit module 10c, and a description of the same or similar configuration will be omitted. The circuit module 10d is able to produce the same operational effects as the circuit module 10c.

### Fifth Modification

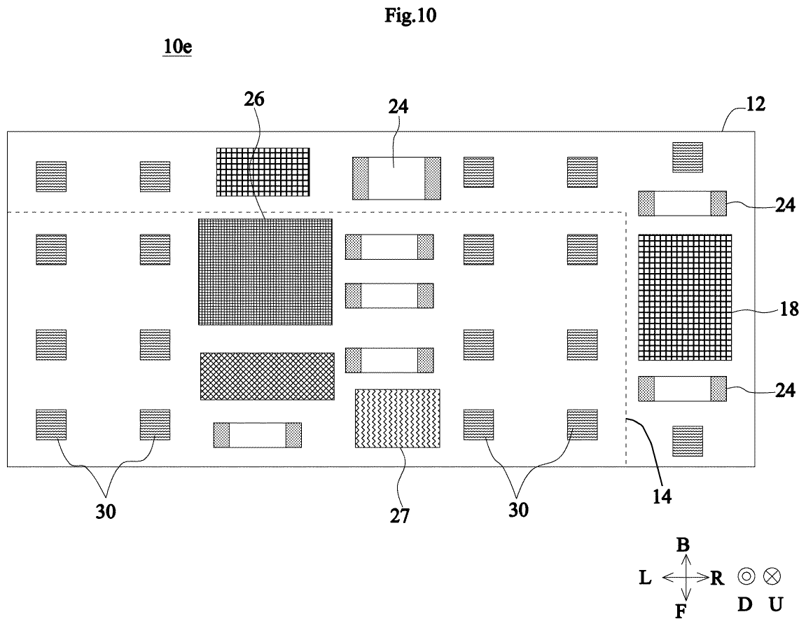

Hereinafter, a circuit module 10e according to a fifth modification of the present disclosure will be described with reference to drawings. FIG. 10 is a view of a first lower principal surface S2 of the circuit module 10e viewed in the up direction.

The circuit module 10e is different in the shape of the lower circuit board 14 from the circuit module 10. More specifically, the back long side and the right short side of the lower circuit board 14, when viewed in the up-down direction, do not overlap with the back long side and the right short side of the upper circuit board 12. Other structures of the circuit module 10e are the same as or similar to the structures of the circuit module 10, and a description of the same or similar configuration will be omitted. The circuit module 10e is able to produce the same operational effects as the circuit module 10.

### Sixth Modification

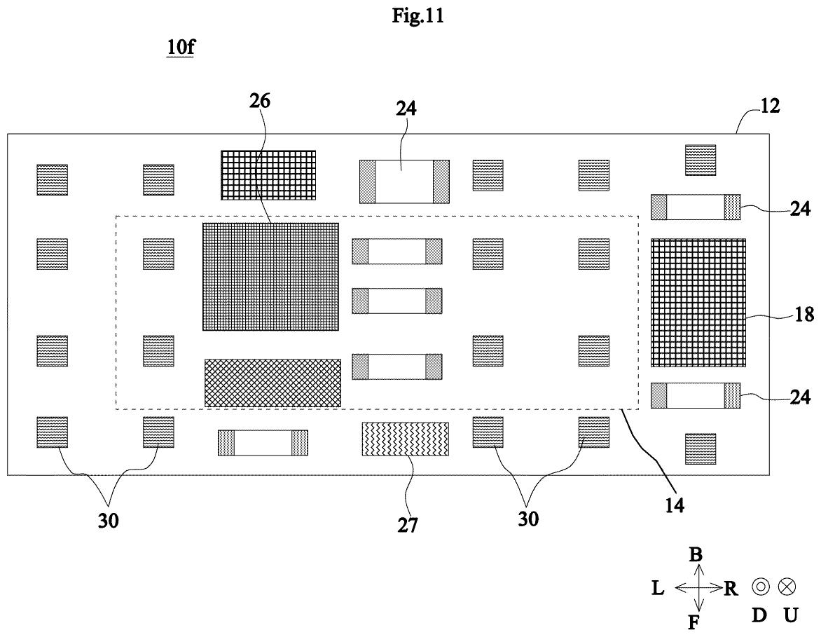

Hereinafter, a circuit module 10f according to a sixth modification of the present disclosure will be described with reference to drawings. FIG. 11 is a view of a first lower principal surface S2 of the circuit module 10f viewed in the up direction.

The circuit module 10f is different in the shape of the lower circuit board 14 from the circuit module 10. More specifically, the outer end of the lower circuit board 14, when viewed in the up-down direction, does not overlap with an outer end of the upper circuit board 12. In other words, the lower circuit board 14, when viewed in the up-down direction, fits in the outer end of the upper circuit board 12. Other structures of the circuit module 10f are the same as or similar to the structures of the circuit module 10, and a description of the same or similar configuration will be omitted. The circuit module 10f is able to produce the same operational effects as the circuit module 10.

### Seventh Modification

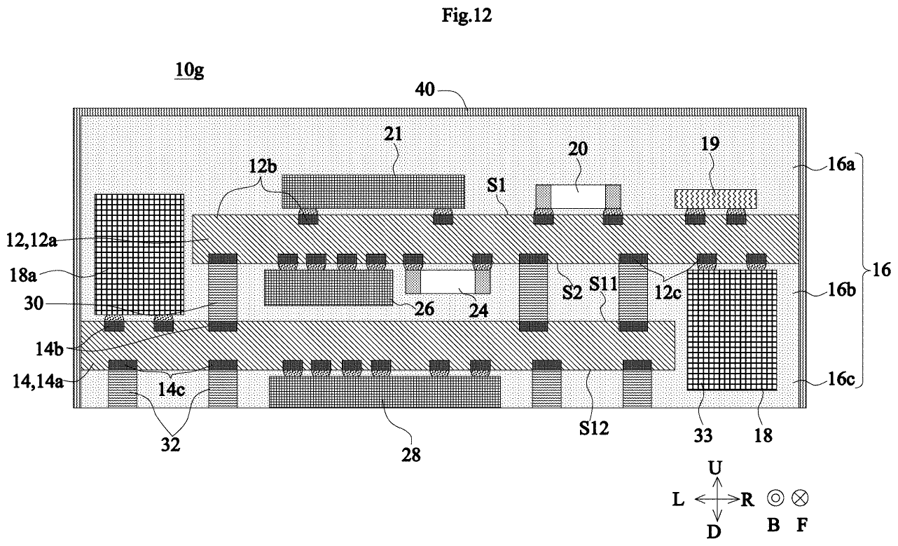

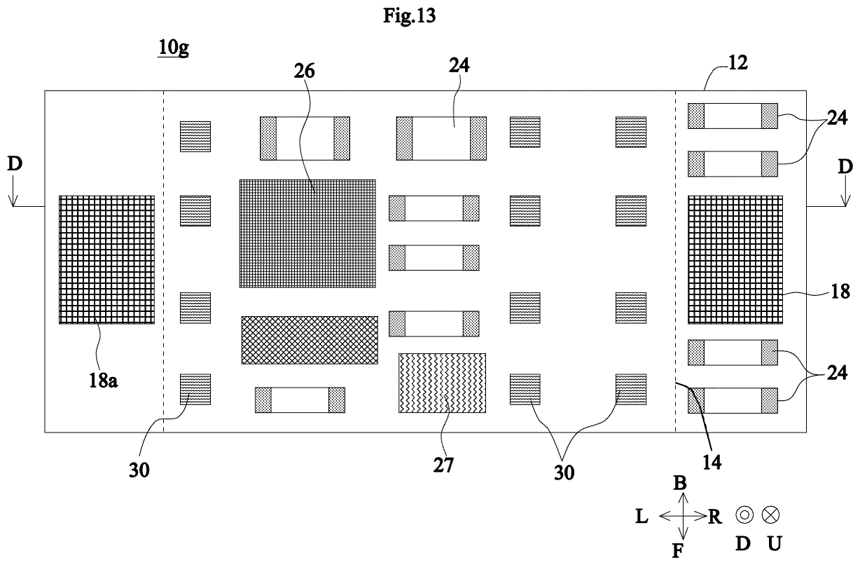

Hereinafter, a circuit module 10g according to a seventh modification of the present disclosure will be described with reference to drawings. FIG. 12 is a cross-sectional view of the circuit module 10g. FIG. 12 shows, for example, a cross-section taken along a line D-D in FIG. 13. FIG. 13 is a view of a first lower principal surface S2 of the circuit module 10g viewed in the up direction.

The circuit module 10g is different from the circuit module 10 in the way the upper circuit board 12 and the lower circuit board 14 overlap with each other. More specifically, the lower circuit board 14 projects from the upper circuit board 12 in a left direction. The upper circuit board 12 projects from the lower circuit board 14 in a right direction. In addition, the circuit module 10g further includes an electronic component (a second component) 18a mounted on the second upper principal surface S11. When viewed in the up-down direction, the electronic component (the second component) 18a is located outside the outer end of the upper circuit board 12. In the present exemplary embodiment, the electronic component 18a is located on the left of the upper circuit board 12. Then, an upper end of the electronic component 18a is located above the first lower principal surface S2. The electronic component 18a, for example, is an inductor included in the matching circuit 52b of the reception circuit 52. Other structures of the circuit module 10g are the same as or similar to the structures of the circuit module 10, and a description of the same or similar configuration will be omitted. The circuit module 10g is able to produce the same operational effects as the circuit module 10.

In the circuit module 10g, the upper end of the electronic component 18a is located above the first lower principal surface S2. Accordingly, the electronic component 18a is brought close to the shield member 40. As a result, the electronic component 18a is shielded by the shield member 40.

### Other Exemplary Embodiments

The circuit module according to the present disclosure is not limited to the circuit modules 10 and 10a to 10g and various changes and modifications may be possible within the scope of the present disclosure. In addition, the structures of the circuit modules 10 and 10a to 10g may be optionally combined.

It is to be noted that the connection members 30, 32, 33, and 34 of the circuit modules 10b to 10g may be solder bumps.

It is to be noted that the number of connection members (second connection members) 33 may be one or more.

It is to be noted that the number of connection members 34 may be one or more.

It is to be noted that the electronic components 18 and 18a may be elements other than an inductor.

It is to be noted that the electronic component 18, when viewed in the up-down direction, may not overlap with the electronic component 19 being the power amplifier 50a.

It is to be noted that the number of connection members (first connection members) 30 may be one or more.

It is to be noted that the connection members 30, 32, 33, and 34 are not essential components.

It is to be noted that the electronic components 19, 21, 26, and 28 and the plurality of electronic components 20 and 24 are not essential components.

It is to be noted that the sealing portions 16a and 16c are not essential components.

It is to be noted that a through hole that passes through the upper circuit board 12 in the up-down direction may be provided.

It is to be noted that the upper circuit board 12, when viewed in the up-down direction, may have a shape other than a rectangular shape.

The present disclosure includes the following structures.

(1) A circuit module including an upper circuit board including a first upper principal surface and a first lower principal surface that are arranged in an up-down direction, a lower circuit board including a second upper principal surface and a second lower principal surface that are arranged in the up-down direction and disposed below the upper circuit board, a first component mounted on the first lower principal surface, a sealing member covering the first lower principal surface and the second upper principal surface, and a shield member, and the lower circuit board, when viewed in the up-down direction, overlaps with a portion of the upper circuit board, the upper circuit board, the lower circuit board, and the sealing member configure a main body portion including an upper surface, a lower surface, and a side surface connecting the upper surface and the lower surface, the shield member covers the side surface, when viewed in the up-down direction, the first component is located outside an outer end of the lower circuit board, a lower end of the first component is located below the second upper principal surface, and, when viewed in the up-down direction, a component mounted on the first lower principal surface and a connection member mounted on the first lower principal surface are absent between the side surface located closest to the first component and the first component.

(2) The circuit module according to (1) in which the first component is an inductor.

(3) The circuit module according to (2) in which the circuit module has a transmission circuit and a reception circuit, and the first component is included in the transmission circuit.

(4) The circuit module according to (3) in which the circuit module further includes a power amplifier included in the transmission circuit and mounted on the first upper principal surface, and the power amplifier, when viewed in the up-down direction, overlaps with the first component.

(5) The circuit module according to any one of (1) to (4) in which the circuit module further includes one or more first connection members mounted on the first lower principal surface and the second upper principal surface, and electrically connecting the upper circuit board and the lower circuit board.

(6) The circuit module according to (5) in which the first connection member is a metal pin extending in the up-down direction.

(7) The circuit module according to (5) in which the first connection member is a solder bump.

(8) The circuit module according to any one of (1) to (7) in which the circuit module further includes one or more second connection members, when viewed in the up-down direction, located outside the outer end of the lower circuit board, mounted on the first lower principal surface, and exposed outside the main body portion on the lower surface of the main body portion.

(9) The circuit module according to (8) in which the one or more second connection members are connected to a ground potential, and the component mounted on the first lower principal surface or the connection member mounted on the first lower principal surface is absent between a portion of the one or more second connection members and the first component.

(10) The circuit module according to (9) in which the one or more second connection members, when viewed in the up-down direction, are placed around the first component.

(11) The circuit module according to any one of (1) to (10) in which the circuit module further includes a second component mounted on the second upper principal surface, and, when viewed in the up-down direction, the second component is located outside an outer end of the upper circuit board.

(12) The circuit module according to any one of (1) to (11) in which the upper circuit board, when viewed in the up-down direction, has a rectangular shape having a front long side, a back long side, a left short side, and a right short side, and the outer end of the lower circuit board, when viewed in the up-down direction, overlaps with at least a portion of at least two sides among the front long side, the back long side, the left short side, and the right short side of the upper circuit board.

(13) The circuit module according to any one of (1) to (11) in which the outer end of the lower circuit board, when viewed in the up-down direction, does not overlap with the outer end of the upper circuit board.
10, 10a to 10g: circuit module
11: main body portion
12: upper circuit board
12a, 14a: board body
12b, 12c, 14b, 14c: mounting electrode
14: lower circuit board
16: sealing member
16a to 16c: sealing portion
18, 18a, 19 to 21, 24, 26 to 28: electronic component
30, 32 to 34: connection member
40: shield member
50: transmission circuit
50a: power amplifier
50b: matching circuit
50c: filter
52: reception circuit
52a: filter
52b: matching circuit
52c: low noise amplifier
56: switch IC
Rx: reception signal
S1: first upper principal surface
S11: second upper principal surface
S12: second lower principal surface
S2: first lower principal surface
Tx: transmission signal

1. A circuit module comprising:
an upper circuit board including a first upper principal surface and a first lower principal surface, the first upper principal surface and the first lower principal surface being arranged in an up-down direction;
a lower circuit board including a second upper principal surface and a second lower principal surface, the second upper principal surface and the second lower principal surface being arranged in the up-down direction and disposed below the upper circuit board;
a first component mounted on the first lower principal surface;
a sealing member covering the first lower principal surface and the second upper principal surface; and
a shield member, wherein:
the lower circuit board, when viewed in the up-down direction, overlaps with a portion of the upper circuit board;
the upper circuit board, the lower circuit board, and the sealing member configure a main body portion including an upper surface, a lower surface, and a side surface connecting the upper surface and the lower surface;
the shield member covers the side surface;
when viewed in the up-down direction, the first component is located outside an outer end of the lower circuit board;
a lower end of the first component is located below the second upper principal surface; and
when viewed in the up-down direction, another component mounted on the first lower principal surface and a connection member mounted on the first lower principal surface are absent between a portion of the side surface located closest to the first component and the first component.

2. The circuit module according to claim 1, wherein the first component is an inductor.

3. The circuit module according to claim 2, wherein:
the circuit module has a transmission circuit and a reception circuit; and
the first component is included in the transmission circuit.

4. The circuit module according to claim 3, wherein:
the circuit module further includes a power amplifier included in the transmission circuit and mounted on the first upper principal surface; and
the power amplifier, when viewed in the up-down direction, overlaps with the first component.

5. The circuit module according to claim 1, wherein the circuit module further includes one or more first connection members mounted on the first lower principal surface and the second upper principal surface, and electrically connecting the upper circuit board and the lower circuit board.

6. The circuit module according to claim 5, wherein the first connection member is a metal pin extending in the up-down direction.

7. The circuit module according to claim 5, wherein the first connection member is a solder bump.

8. The circuit module according to claim 1, wherein the circuit module further includes one or more second connection members, when viewed in the up-down direction, located outside the outer end of the lower circuit board, mounted on the first lower principal surface, and exposed outside the main body portion on the lower surface of the main body portion.

9. The circuit module according to claim 8, wherein:
the one or more second connection members are connected to a ground potential; and
the other component mounted on the first lower principal surface or the connection member mounted on the first lower principal surface is absent between a portion of the one or more second connection members and the first component.

10. The circuit module according to claim 9, wherein the one or more second connection members, when viewed in the up-down direction, are placed around the first component.

11. The circuit module according to claim 1, wherein:
the circuit module further includes a second component mounted on the second upper principal surface; and
when viewed in the up-down direction, the second component is located outside an outer end of the upper circuit board.

12. The circuit module according to claim 1, wherein:
the upper circuit board, when viewed in the up-down direction, has a rectangular shape having a front long side, a back long side, a left short side, and a right short side; and
the outer end of the lower circuit board, when viewed in the up-down direction, overlaps with at least a portion of at least two sides among the front long side, the back long side, the left short side, and the right short side of the upper circuit board.

13. The circuit module according to claim 1, wherein the outer end of the lower circuit board, when viewed in the up-down direction, does not overlap with the outer end of the upper circuit board.

14. The circuit module according to claim 2, wherein the circuit module further includes one or more first connection members mounted on the first lower principal surface and the second upper principal surface, and electrically connecting the upper circuit board and the lower circuit board.

15. The circuit module according to claim 3, wherein the circuit module further includes one or more first connection members mounted on the first lower principal surface and the second upper principal surface, and electrically connecting the upper circuit board and the lower circuit board.

16. The circuit module according to claim 4, wherein the circuit module further includes one or more first connection members mounted on the first lower principal surface and the second upper principal surface, and electrically connecting the upper circuit board and the lower circuit board.

17. The circuit module according to claim 2, wherein the circuit module further includes one or more second connection members, when viewed in the up-down direction, located outside the outer end of the lower circuit board, mounted on the first lower principal surface, and exposed outside the main body portion on the lower surface of the main body portion.

18. The circuit module according to claim 3, wherein the circuit module further includes one or more second connection members, when viewed in the up-down direction, located outside the outer end of the lower circuit board, mounted on the first lower principal surface, and exposed outside the main body portion on the lower surface of the main body portion.

19. The circuit module according to claim 4, wherein the circuit module further includes one or more second connection members, when viewed in the up-down direction, located outside the outer end of the lower circuit board, mounted on the first lower principal surface, and exposed outside the main body portion on the lower surface of the main body portion.

20. The circuit module according to claim 5, wherein the circuit module further includes one or more second connection members, when viewed in the up-down direction, located outside the outer end of the lower circuit board, mounted on the first lower principal surface, and exposed outside the main body portion on the lower surface of the main body portion.
